(19) United States
(12) Patent Application Publication
(10) Pub. No.: US 2009/0231167 A1
(43) Pub. Date: Sep. 17, 2009

(54) LIGHT SOURCE ADJUSTING AND CONTROLLING SWITCH DEVICE

(75) Inventor: CHING-NAN CHEN, TAIPEI CITY (TW)

Correspondence Address: CHING-NAN CHEN, P.O. BOX 108-00403, TAIPEI, 106, omitted

(73) Assignee: CHING-NAN CHEN, TAIPEI CITY (TW)

(21) Appl. No.: 12/399,044

(22) Filed: Mar. 6, 2009

(30) Foreign Application Priority Data
Mar. 12, 2008 (TW) 097204245

(51) Int. Cl. H03K 17/94

(52) U.S. Cl. 341/22

(57) ABSTRACT

The present invention provides a light source adjusting and controlling switch device, which comprises a control circuit, and a capacitance-type touch pad mounted on the surface of a lamp and connected to the control circuit. The capacitance-type touch pad has a plurality detection element and is electrically connected with a touch sensor of the control circuit. When a user touches the capacitance-type touch pad with a finger, a capacitance will be produced on the capacitance-type touch pad, and the plurality of detection element can sense the position of the finger and produce a corresponding capacitance variable amount signal. After the touch sensor receives the signal, a microprocessor of the control circuit will operate the switch on/off, the brightness and color to a connected light emitting device immediately.

This application claims the priority benefit of Taiwan patent application number 097204245 filed on Mar. 12, 2008.

### BACKGROUND OF THE INVENTION

1. Field of the Invention

The present invention relates generally to a light source adjusting and controlling a switch device, which uses a capacitance-type touch pad to switch the brightness of light sources or different colors.

2. Description of the Related Art

Conventional lamps used in rooms must be adjusted in brightness according to different conditions. For example, the brightness of a lamp will be turned down when people exit a room or sleep, in order to save electrical power; while maintaining enough light for vision. However, the brightness in most conventional lamps cannot be adjusted and only switched on or off. Some conventional lamps use the sectional switch to control the brightness. However, over periods of time, the contact spring inside the sectional switch will be weakened and cause poor contact; which in turn affects lighting adjustments. Some conventional lamps use a resistance-type touch pad to control brightness. The lamps, turned on by a first touch, become brighter at the second touch and turns off at the third touch. Brightness of the lamp is controlled by sections; therefore, other brightness changes cannot be adjusted precisely.

### SUMMARY OF THE INVENTION

The present invention has been accomplished to provide a light source adjusting and controlling switch device that eliminates the aforesaid drawbacks. According to one aspect of the present invention, the light source adjusting and controlling switch device is installed in a lamp, and comprises a control circuit inside and a capacitance-type touch pad on the surface for allowing a user to touch with a finger. The capacitance-type touch pad has a plurality of detection elements electrically connected to a touch sensor of the control circuit. When the user touches the capacitance-type touch pad with a finger, a capacitance will be produced on the capacitance-type touch pad, and the plurality of detection elements will sense the position of the finger to produce corresponding signals. After the touch sensor receives the signal, a microprocessor of the control circuit will operate immediately to switch on/off, brightness and colors to a connected light emitting device according to the signal. Thus, the design does not need any extra special tools and can be operated by only the touch of a finger. Furthermore, the design can execute multi-point movement and operation simultaneously and immediately, solving the difficult recognition in the prior art.

According to a second aspect of the present invention, the light source adjusting and controlling switch device can be installed in a wall switch. The control circuit is electrically connected to a light source in the room, and the capacitance-type touch pad is on the surface of the wall switch. When the user wants to adjust or control the brightness of the light source, the user can touch the capacitance-type touch pad with a finger or simply move the finger on the capacitance-type touch pad. Immediately the plurality of detection elements of the capacitance-type touch pad will sense the capacitance variable amount, and allow the user to further adjust and control brightness (such as the least bright, less bright, bright, brighter and the brightest) gradually and precisely through a sectional touch/control method, instead of a conventional turning switch. For additional convenience the capacitance-type touch pad is designed with an additional fluorescence indicating function at night. Also, if a three way light switch is not currently used for supplying power to the light source, the invention will supply an additional battery powered device mounted in the capacitance-type touch pad on the wall switch, which will supply the necessary power to the microprocessor. The invention therefore, provides power to adjust and control the brightness and color of the light.

According to an additional aspect of the present invention, when the user touches the capacitance-type touch pad with a finger, adjustment or control of the brightness for even conventional light sources such as tungsten or halogen lamps, can immediately be achieved. When the user touches the capacitance-type touch pad, equipped with a battery powered device, with a finger, adjustment or control of the brightness for conventional light sources such as fluorescent lights, electronic lamps and energy-efficient lamps. Another added aspect of the present invention, is that the light source adjusting and controlling switch device can be installed in a remote controller. The control circuit, in the remote controller, contains a transfer circuit for sending a remote signal directly to the light source or to the receiving circuit located within the touch pad on the wall.

When the user operates the capacitance-type touch pad on the remote controller with a finger, the detection elements will sense the capacitance variable amounts. It then transmits a signal to the microprocessor within the remote controller, then transfers the remote signal to the wall switch or lamp for adjustment of brightness or color.

### BRIEF DESCRIPTION OF THE DRAWINGS

FIG. 1 is a perspective view of the first preferred embodiment of the present invention.

FIG. 2 is a perspective view of the second preferred embodiment of the present invention.

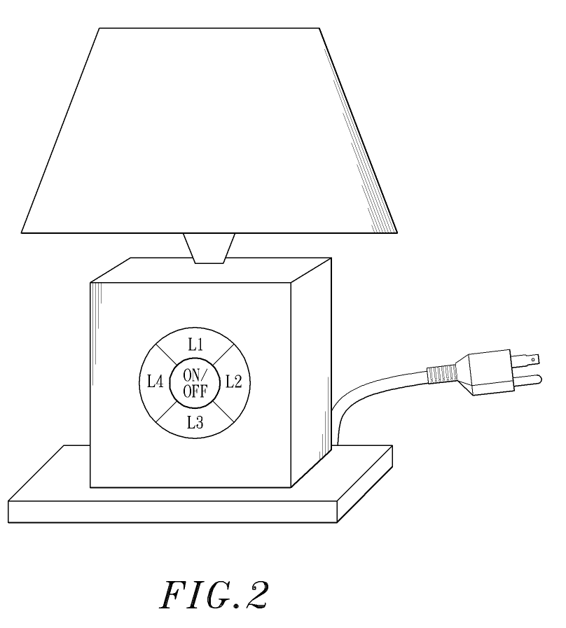

FIG. 3 is a block diagram of the first and second preferred embodiments of the present invention.

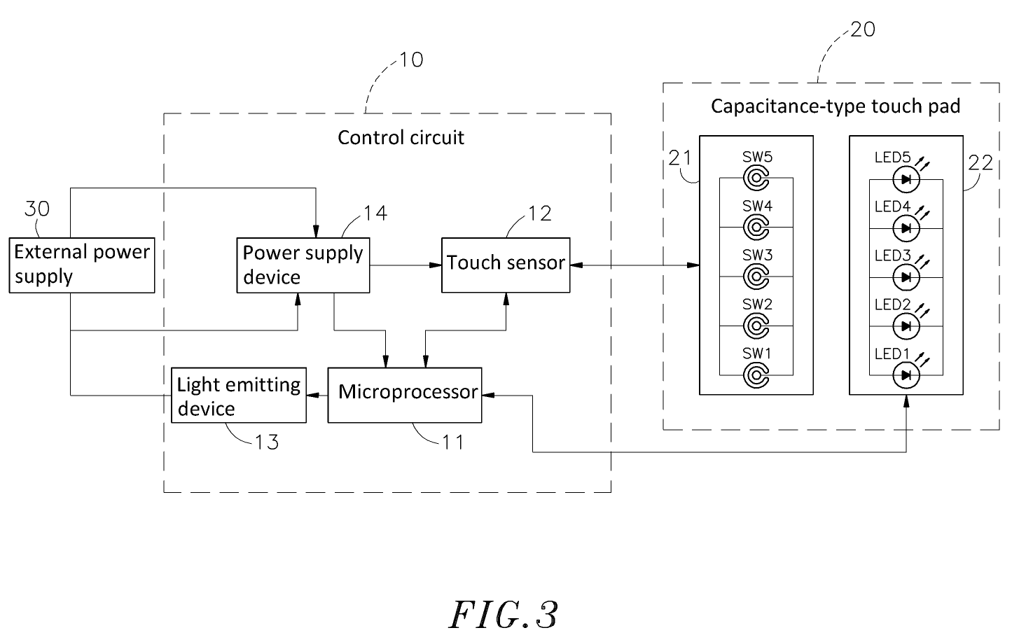

FIG. 4 is a circuit diagram (I) of the first and second preferred embodiments of the present invention.

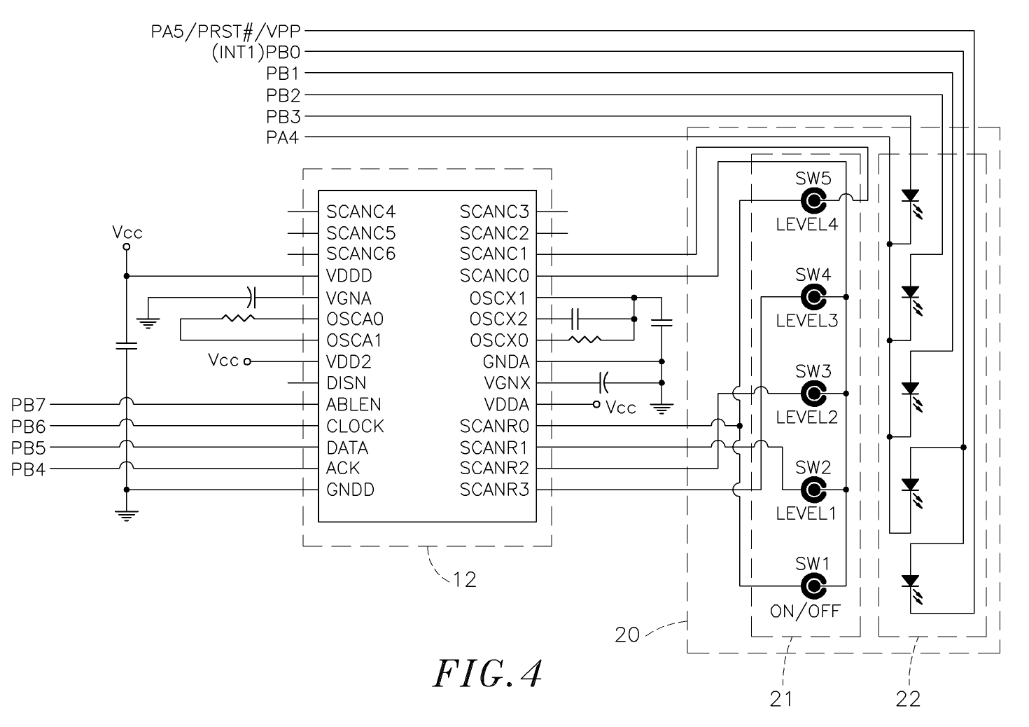

FIG. 5 is a circuit diagram (II) of the first and second preferred embodiments of the present invention.

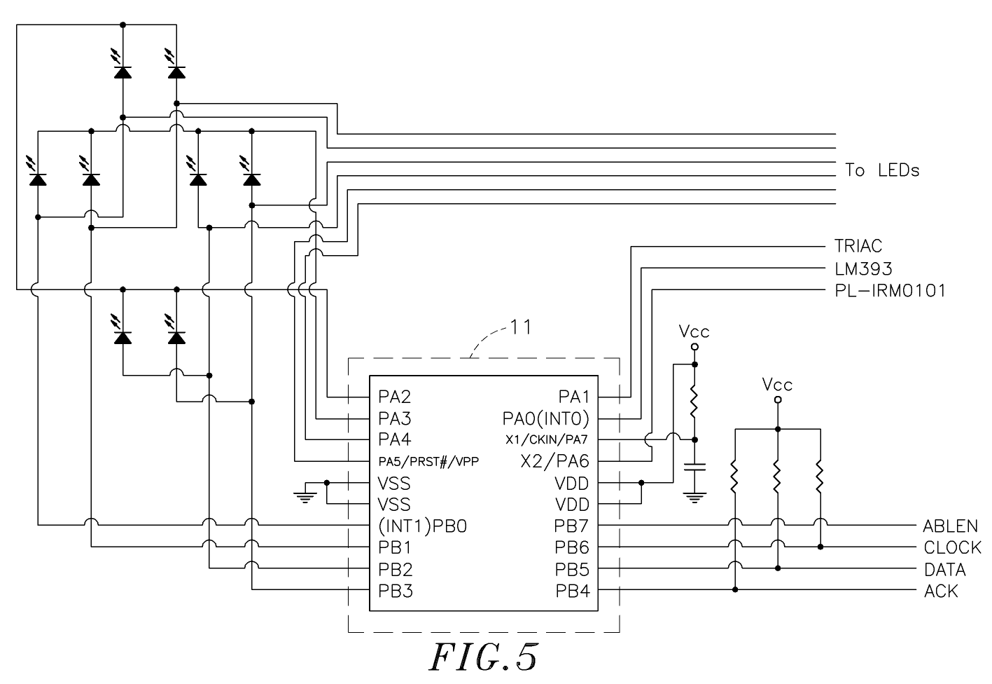

FIG. 6 is a circuit diagram (III) of the first and second preferred embodiments of the present invention.

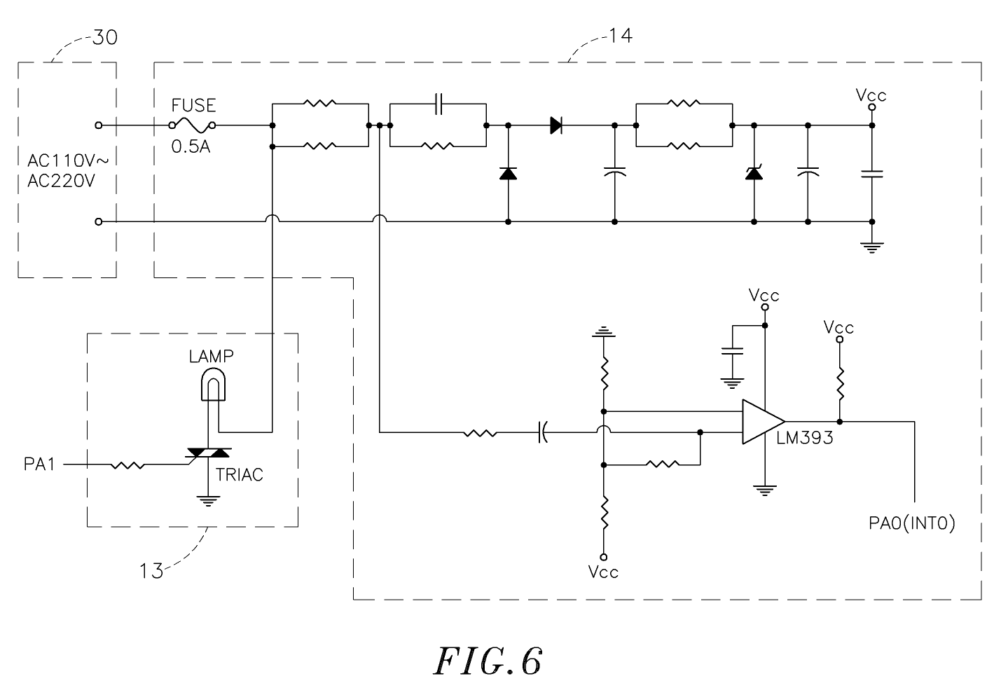

FIG. 7 is a perspective view (I) of the third preferred embodiment of the present invention.

FIG. 8 is a perspective view (II) of the third preferred embodiment of the present invention.

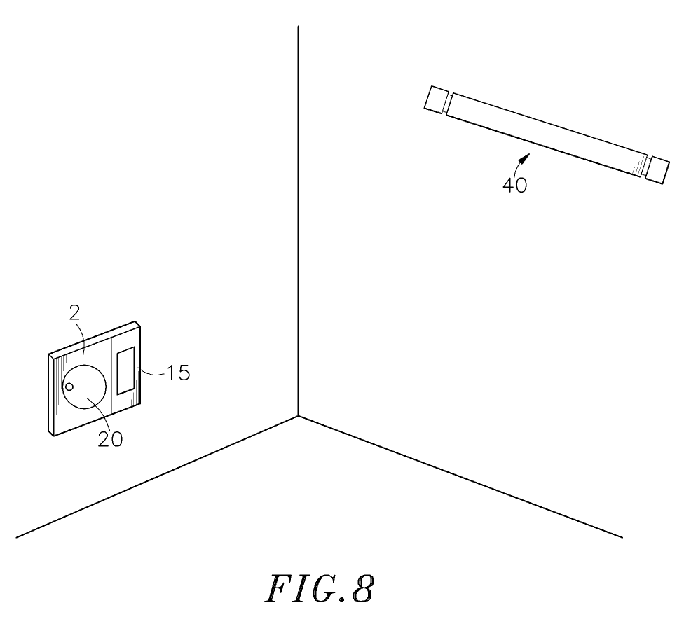

FIG. 9 is a perspective view (III) of the third preferred embodiment of the present invention.

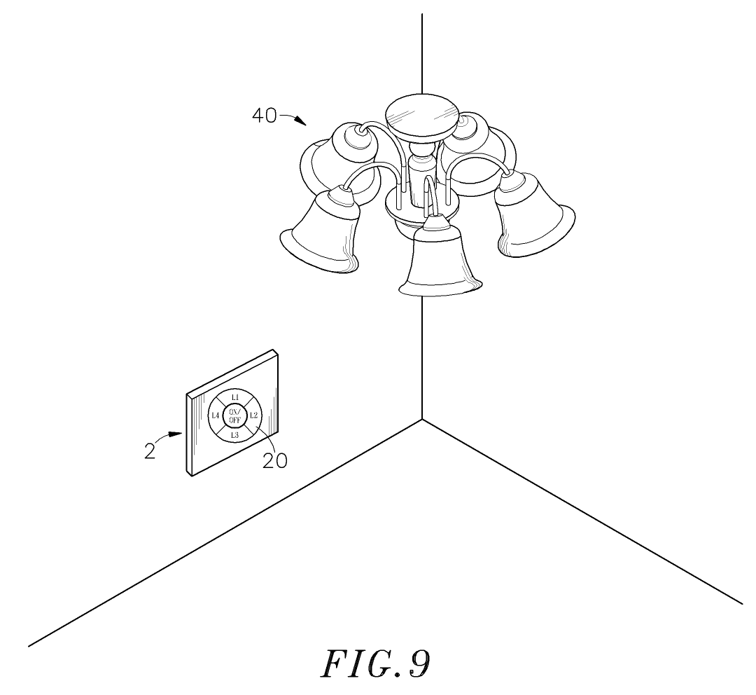

FIG. 10 is a block diagram of the third preferred embodiment of the present invention.

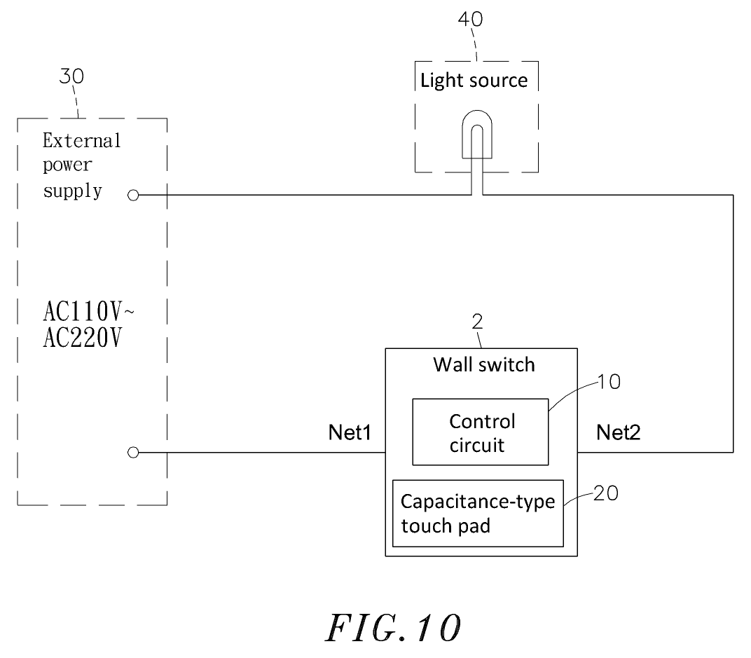

FIG. 11 is a circuit diagram (I) of the third preferred embodiment of the present invention.

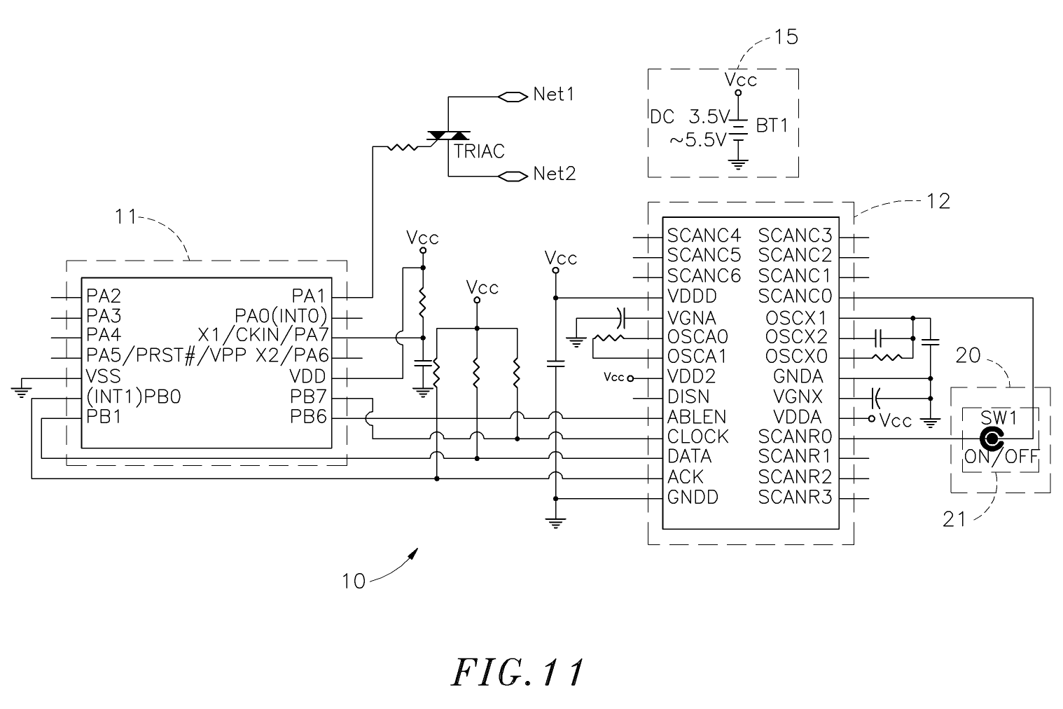

FIG. 12 is a circuit diagram (II) of the third preferred embodiment of the present invention.

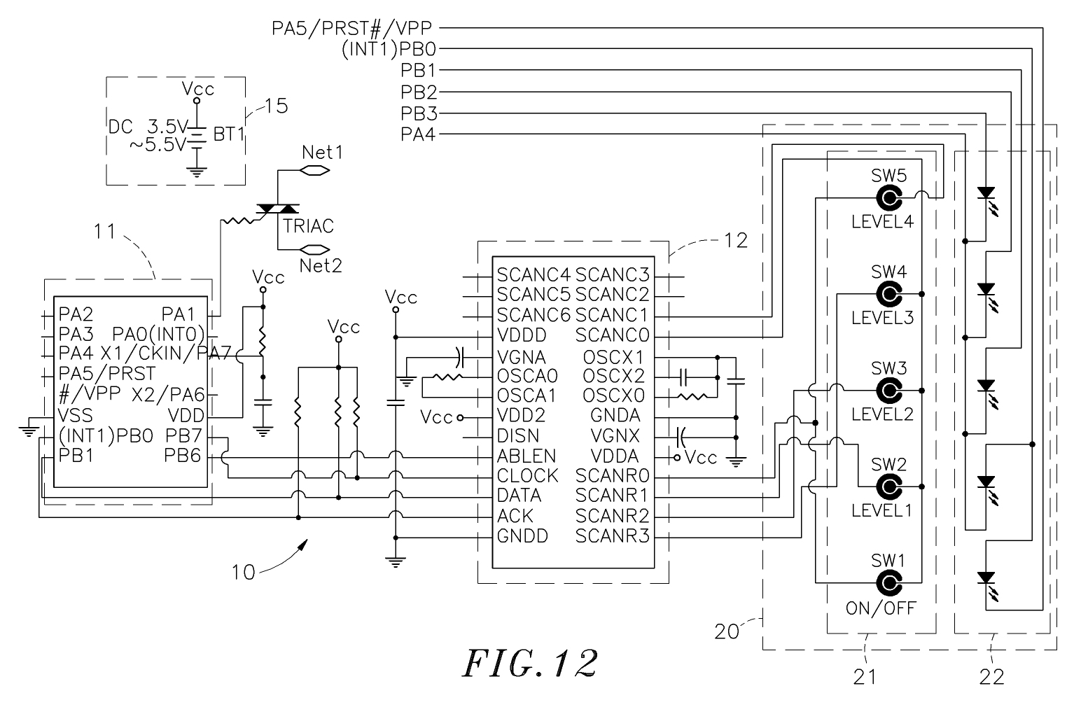

FIG. 13 is a perspective view (I) of the fourth preferred embodiment of the present invention.

FIG. 14 is a perspective view (II) of the fourth preferred embodiment of the present invention.

FIG. 15 is a block diagram of the fourth preferred embodiment of the present invention.

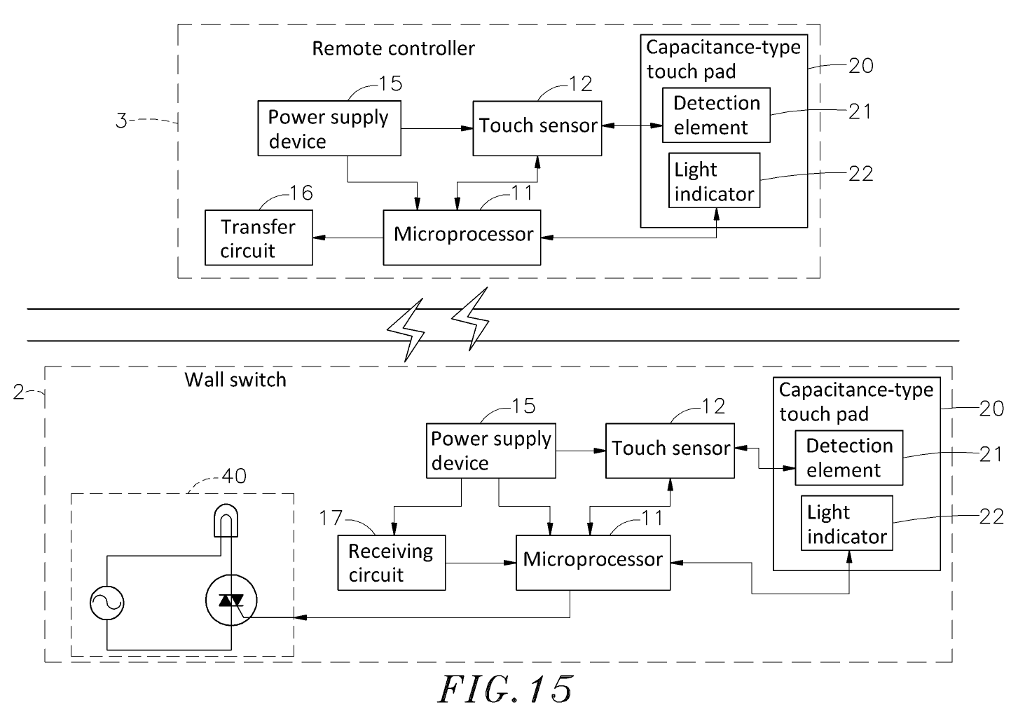

FIG. 16 is a circuit diagram (I) of the fourth preferred embodiment of the present invention.

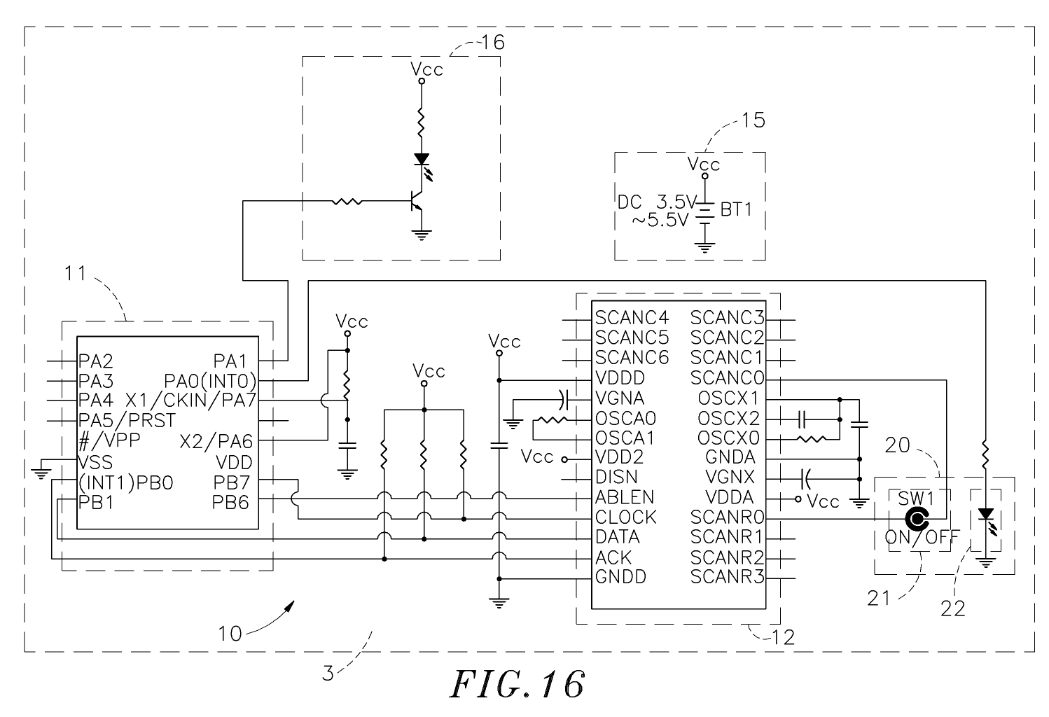

FIG. 17 is a circuit diagram (II) of the fourth preferred embodiment of the present invention.

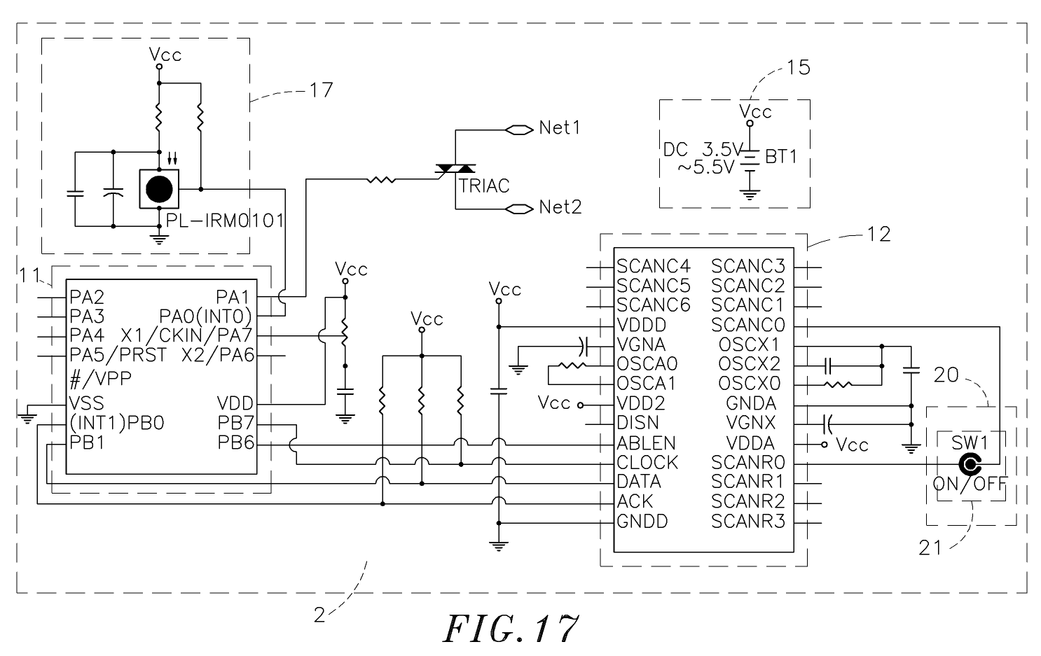

FIG. 18 is a perspective view of the fifth preferred embodiment of the present invention.

FIG. 19 is a block diagram of the fifth preferred embodiment of the present invention.

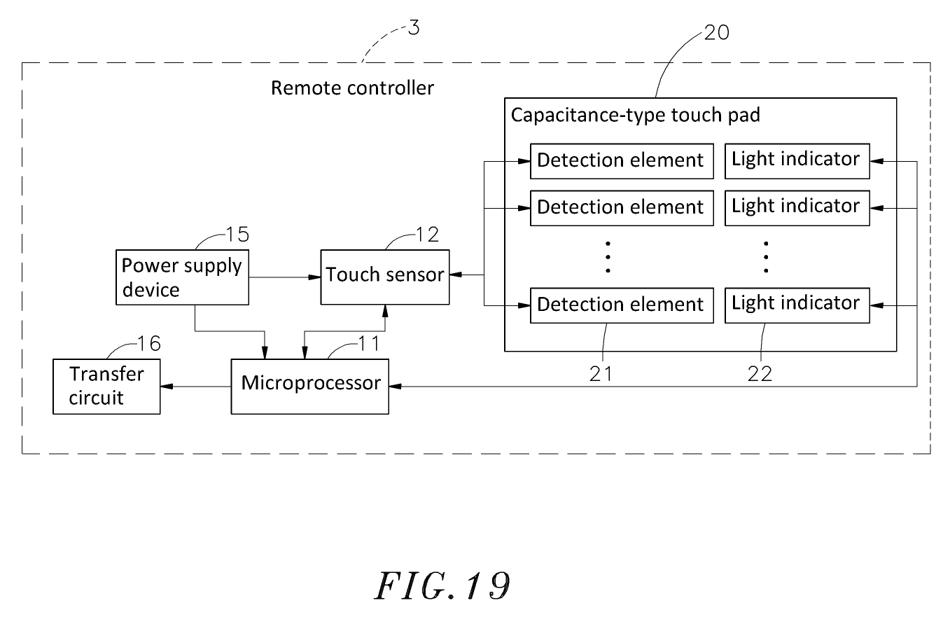

FIG. 20 is a perspective view of the sixth preferred embodiment of the present invention.

FIG. 21 is a block diagram of the sixth preferred embodiment of the present invention.

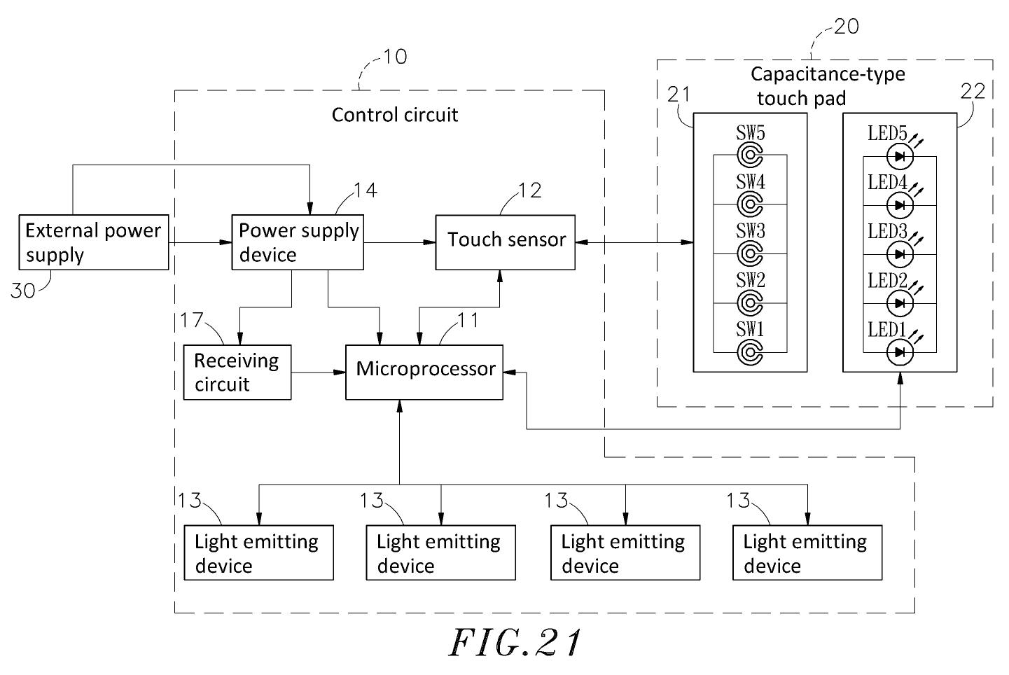

### DETAILED DESCRIPTION OF THE PREFERRED EMBODIMENT

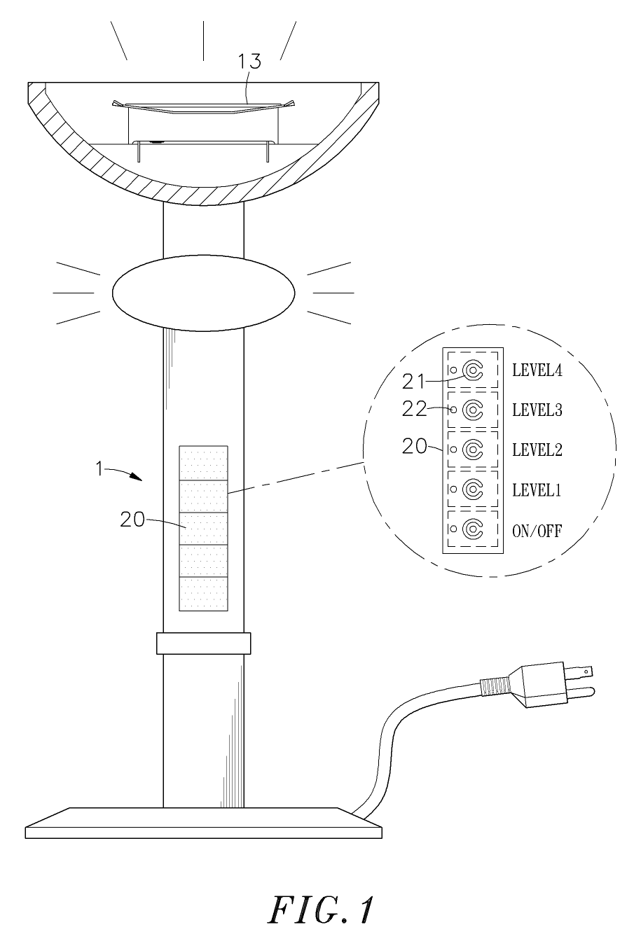

FIGS. 1˜6 show the first and second preferred embodiments of the present invention. In the two embodiments, a light source adjusting and controlling switch device is installed in a lamp 1, having a control circuit 10 inside, and a capacitance-type touch pad 20 on the surface thereof. The control circuit 10 comprises a microprocessor 11, a touch sensor 12, a light emitting device 13 and a power supply device 14. Furthermore, the capacitance-type touch pad 20 comprises a plurality of detection elements 21 and a plurality of light indicator 22 corresponding to the detection elements 21. The detection elements 21 and the light indicators 22 of the capacitance-type touch pad 20 are electrically connected with the touch sensor 12 and the microprocessor 11 of the control circuit 10 inside the lamp 1 respectively.

When in use, the power supply device 14 is connected to an external power supply 30, namely AC110V˜AC220V, and AC shall be transformed into DC and sent to the control circuit 10 and the capacitance-type touch pad 20. When a user touches the capacitance-type touch pad 20 with a finger for adjusting and controlling the light emitting device 13, the finger will produce a capacitance on the capacitance-type touch pad 20. The plurality of detection elements 21 will sense the position of the finger on the capacitance-type touch pad 20 and trace the movement of the capacitance to precisely locate the finger's position. Meanwhile, a capacitance variable amount formed on the capacitance-type touch pad 20 is measured, and a signal corresponding to the capacitance variable amount is sent to the touch sensor 12 for confirmation. The microprocessor 11 can then perform a relative control to the light emitting device 13 according to the signal.

For example, when the user moves a finger on the capacitance-type touch pad 20, one of the detection elements 21 on the capacitance-type touch pad 20 will detect that a signal is changing. Then, the correctness of the touch signal will be confirmed by the touch sensor 12 and inform the microprocessor 11 with a corresponding signal to allow the microprocessor 11 to adjust and control the brightness of the light emitting device 13. Through the finger movement on the capacitance-type touch pad 20, the brightness of the light emitting device 13 can be adjusted and controlled from the darkest to the brightest or from the brightest to the darkest. The sectional touch/control method can adjust and control the brightness of the light emitting device 13 from the darkest to the brightest (such as the least bright, less bright, bright, brighter and the brightest) or from the brightest to the darkest (such as the brightest, brighter, bright, less bright and the least bright), and can carry out the action of turning on and turning off. Through finger movement on the capacitance-type touch pad 20, the brightness of the light emitting device 13 can be finely adjusted and controlled immediately. If the light emitting device 13 has different colors, the user can also touch the capacitance-type touch pad 20 to switch between different colors.

The capacitance-type touch pad 20 of the present invention has a non-single point press with durable use characteristics. The user can use a finger to operate a lamp 1, with no need of any special tools. Therefore, the capacitance-type touch pad 20 has better reliability and a longer use period. The pressure of the touch to a capacitance-type touch pad 20 does not need great exertion like that of a resistance-type touch pad; and the user can precisely position the desired light by using only a light touch. More importantly, the conventional resistance-type touch pad can only be operated by a single finger-single direction mode; however, the capacitance-type touch pad 20 of the present invention can execute the multi-point movement and operation simultaneously and immediately, which solves the difficult recognition of the prior art.

In the above-preferred embodiment, when the user moves a finger on the capacitance-type touch pad 20, because the capacitance variable amount can be sensed by the detection elements 21; therefore, the light indicators 22 corresponding to the detection elements 21 will remain on in order to show the press status and to guide the user to adjustment of the brightness of the light emitting device 13. The capacitance-type touch pad 20 can be a transparent board, and a fluorescent agent can be added into the capacitance-type touch pad 20 to enable the capacitance-type touch pad 20 to produce the fluorescence for indicating in darkness.

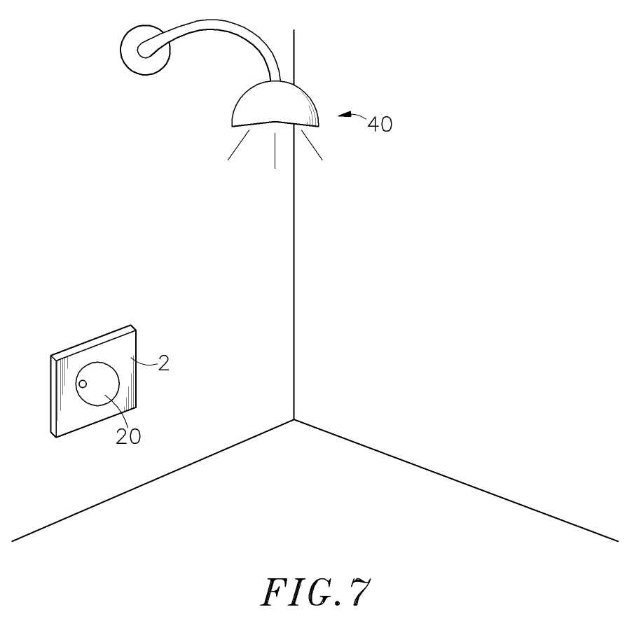

FIGS. 7˜12 are the third preferred embodiment (I), (II) and (III) of the present invention. In this embodiment, the light source adjusting and controlling switch device is mounted inside a wall switch 2. On the surface of the wall switch 2, there is a capacitance-type touch pad 20, with a control circuit 10 electrically connected to a light source 40 (such as fluorescent light, tungsten bulb, power-efficient bulb, LED, search light, sensor light, hanging art lights or other light sources) to replace the conventional switch installed on the wall. If the wall switch 2 is a conventional one-sectional switch (which only includes ON/OFF) and used to turn on/turn off the tungsten or halogen bulbs, the original circuit can supply power to the microprocessor 11, and the touch sensor 12 of the control circuit 10. The touch sensor 12 is also electrically connected with the detection elements 21 of the capacitance-type touch pad 20. Therefore, when the user wants to turn on/turn off the light source 40 in the room, he can touch the capacitance-type touch pad 20 with a finger. At this time, the detection elements 21 sense the capacitance variable amount on the capacitance-type touch pad 20 and the light indicators 22 corresponding to the detection elements 21 will be on to show the press status. The touch sensor 12 then sends a signal, corresponding to the capacitance variable amount, to the microprocessor 11 to enable the microprocessor 11 to turn on/turn off the light source 40. However, if the light source 40 is a fluorescent lamp, an electronic lamp, an energy-efficient light or any other electronic light source, of which the brightness cannot be adjusted, a (battery) power supply device 15 can be installed into the capacitance-type touch pad 20 to become a switch for switching the light source 40.

If the wall switch 20 is a conventional turning switch, it can be replaced with a multi-point capacitance-type touch pad 20, and the original circuit can supply power to the microprocessor 11 and the touch sensor 12 of the control circuit 10. In this way, the brightness of the light source 40 can be adjusted more accurately through the capacitance-type touch pad 20. The plurality of detection elements 21 of the capacitance-type touch pad 20 can sense the position of the finger movement on the capacitance-type touch pad 20 and further sense a capacitance variable amount. A signal corresponding to the capacitance variable amount will be sent to the touch sensor 12 for confirmation. Subsequently, the microprocessor 11 can set the brightness of the light source 40 according to the signal. Through the sectional touch/control method, the user can adjust and control the brightness of the light source 40 from the darkest to the brightest (such as the least bright, less bright, bright, brighter and the brightest) or the brightest to the darkest (such as the brightest, brighter, bright, less bright, least bright). The capacitance-type touch pad 20 can be a transparent board, and a fluorescent agent can be added into the capacitance-type touch pad 20 to make it produce the fluorescence for indicating. If there is no circuit to supply power, a power supply device 15 can be equipped into the capacitance-type touch pad 20 for supplying power to the control circuit 10 inside the wall switch 2 to further adjust the brightness of the light source 40 (such as the adjustable fluorescent light, tungsten lamp, halogen bulb or other adjustable light sources).

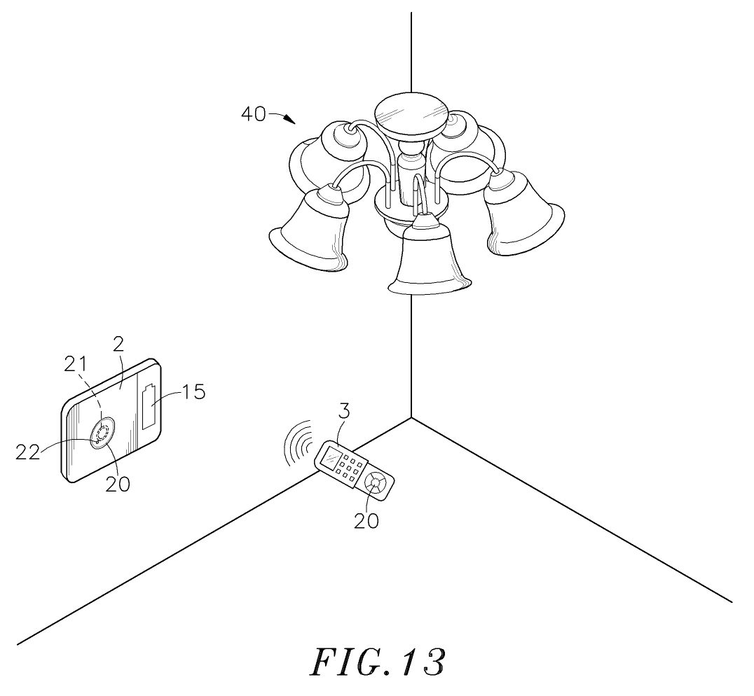

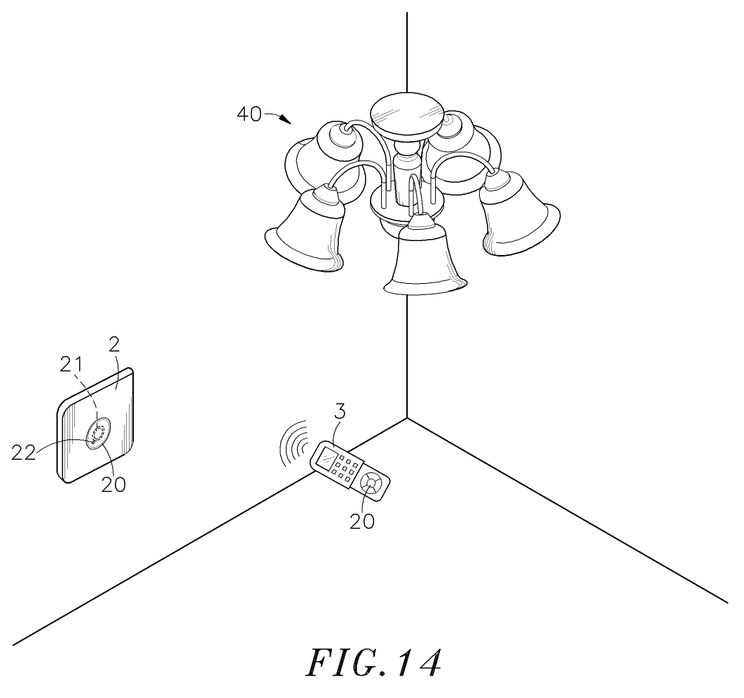

FIGS. 13˜17 are the fourth preferred embodiment (I) and (II) of the present invention. In the embodiment (I) shown in FIG. 13, the light source adjusting and controlling switch devices are set inside a remote controller 3 and a wall switch 2 respectively. In FIG. 13, there is no original circuit in the wall switch 2 to supply power; thus, a power supply device 15 is equipped into the capacitance-type touch pad 20 on the wall switch 2. The microprocessor 11 of the control circuit 10 in the wall switch 2 is electrically connected with a receiving circuit 17. The microprocessor 11 of the control circuit 10 in the remote controller 3 is electrically connected with a transfer circuit 16. When the user operates the capacitance-type touch pad 20 on the remote controller 3 with a finger, the detection elements 21 of the capacitance-type touch pad 20 sense a capacitance variable amount, and the touch sensor 12 sends a signal corresponding to the capacitance variable amount to the microprocessor 11. Next, the microprocessor 11 in the remote controller 3 sends the remote signal through the transfer circuit 16 to the receiving circuit 17 of the control circuit 10 inside the wall switch 2. The wireless transfer mode can be a radio, infrared, Bluetooth technology or other wireless transfer interfaces. After the receiving circuit 17 inside the wall switch 2 receives the signal from the remote controller 3, the microprocessor 11 can switch on/off or set the brightness to the light source 40. The user can also touch the capacitance-type touch pad 20 on the wall switch 2 to directly switch on/off or set the brightness of the light source 40. Through the sectional touch/control method, the user can adjust and control the brightness from the darkest to the brightest (such as the least bright, less bright, bright, brighter and the brightest) or the brightest to the darkest (such as the brightest, brighter, bright, less bright, least bright). The embodiment (II) shown in FIG. 14 is very similar to the embodiment (I) shown in FIG. 13 with exception of the power supply device 15 (the original circuit can supply power to the control circuit 10 in the wall switch 2.).

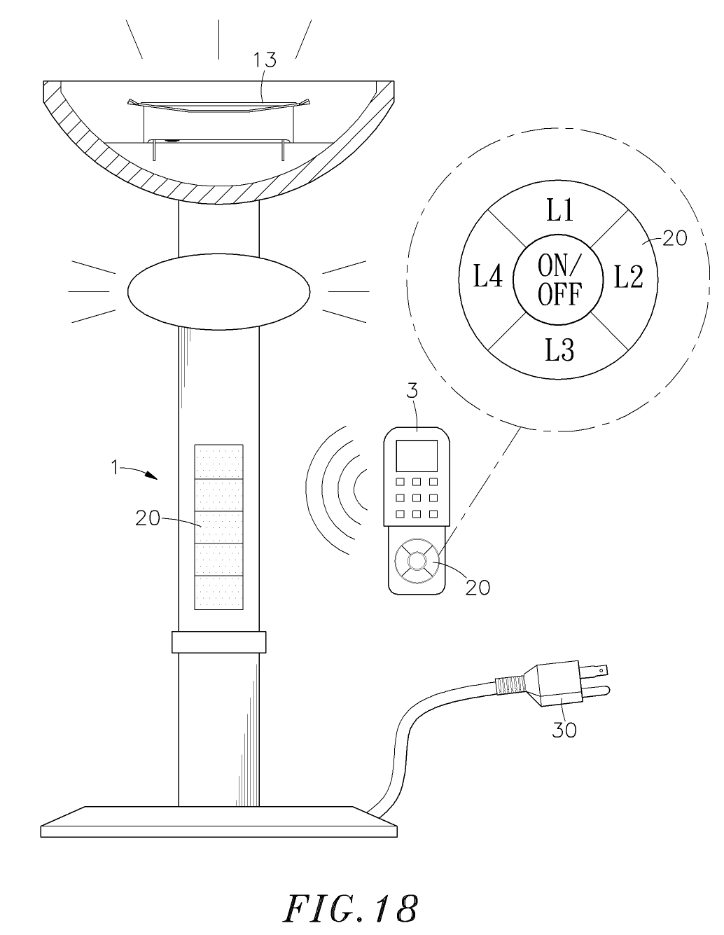

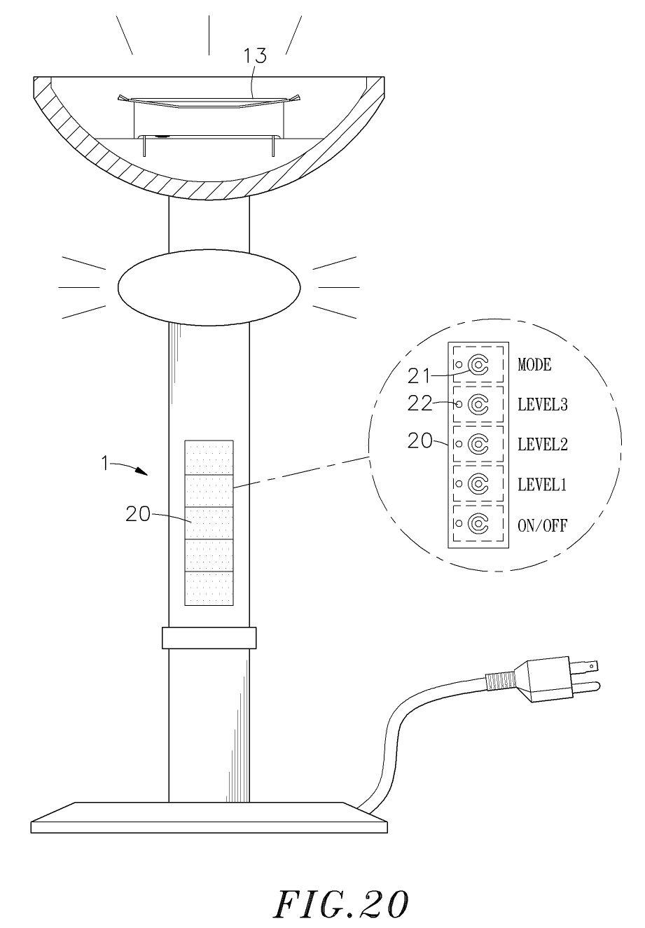

FIGS. 18˜19 are the fifth preferred embodiment of the present invention. This embodiment is substantially similar to the embodiment shown in FIG. 1 with exception of the remote controller 3 and the receiving circuit 17 electrically connected with the microprocessor 11 of the control circuit 1 inside the lamp 1. When the user touches the capacitance-type touch pad 20 on the remote controller 3 with a finger, a remote signal will be sent from the transfer circuit 16 in the remote controller 3 to the receiving circuit 17 of the control circuit 10 inside the lamp 1 to switch on/off or set the brightness to the light emitting device 13 by remote. Through the sectional touch/control method, the user can adjust and control the brightness from the darkest to the brightest (such as the least bright, less bright, bright, brighter and the brightest) or the brightest to the darkest (such as the brightest, brighter, bright, less bright, least bright). FIGS. 20˜21 are the sixth preferred embodiment of the present invention. This embodiment is substantially similar to the embodiment shown in FIG. 1 with exception that the detection elements 21 comprise MODE buttons for switching between the different colors to the light emitting device 13. When the user touches the MODE buttons, the light emitting device 13 will switch the colors.

Although a particular embodiment of the invention has been described in detail for purposes of illustration, various modifications and enhancements may be made without departing from the spirit and scope of the invention. The invention is not to be limited except as by the appended claims.

What the invention claim is:

1. A light source adjusting and controlling switch device, which is installed inside a lamp, comprising:
a control circuit, said control circuit comprising a microprocessor, a touch sensor, a light emitting device, and a supply power device connected with an external power supply to transform AC to DC for supply power; and
a capacitance-type touch pad mounted on a surface of said lamp and connected with said control circuit, comprising a plurality of detection elements connected with said touch sensor of said control circuit; wherein, when a user touches said capacitance-type touch pad with a finger, a capacitance produced on said capacitance-type touch pad will be sensed by said detection elements and further sending a corresponding capacitance variable amount signal to said microprocessor for switch on/off, brightness and color to the said light emitting device immediately.

2. The light source adjusting and controlling switch device as claimed in claim 1, wherein said capacitance-type touch pad further comprises a plurality of light indicators corresponding to the said detection elements on the surface thereof.

3. The light source adjusting and controlling switch device as claimed in claim 1, wherein said capacitance-type touch pad can be a transparent board and adds a fluorescent agent for indicating.

4. The light source adjusting and controlling switch device as claimed in claim 1, wherein said capacitance-type touch pad can operate a multi-set of said light emitting devices for adjusting and controlling the color and the brightness at the same time.

5. A light source adjusting and controlling switch device, which is installed inside a wall switch, comprising:
a control circuit connected with a light source in a room, said control circuit comprising a microprocessor and a touch sensor; and a capacitance-type touch pad mounted on a surface of said wall switch and connected with said control circuit, comprising at least one detection element connected with said touch sensor of said control circuit; wherein, when a user touches said capacitance-type touch pad with a finger, a capacitance produced on said capacitance-type touch pad will be sensed by said at least one detection element and further sending a corresponding capacitance variable amount signal to said microprocessor for switch on/off, brightness and color to said light source immediately.

6. The light source adjusting and controlling switch device as claimed in claim 5, wherein said capacitance-type touch pad further comprises a plurality of light indicator corresponding to the said at least one detection element on the surface thereof.

7. The light source adjusting and controlling switch device as claimed in claim 5, wherein said capacitance-type touch pad can be a transparent board and adds a fluorescent agent for indicating.

8. The light source adjusting and controlling switch device as claimed in claim 5, wherein said capacitance-type touch pad can operate a multi-set of said light source for adjusting and controlling the color and the brightness at the same time.

9. The light source adjusting and controlling switch device as claimed in claim 5, wherein said wall switch is an adjustable brightness switch, and an original circuit in said wall switch can be used to supply power to said microprocessor and said capacitance-type touch pad.

10. The light source adjusting and controlling switch device as claimed in claim 5, wherein said wall switch is a one-sectional switch for switch ON/OFF, and an original circuit in said wall switch can be used to supply power to said microprocessor and said capacitance-type touch pad.

11. The light source adjusting and controlling switch device as claimed in claim 5, wherein said wall switch is further equipped with a supply power device for supply power to said microprocessor and said capacitance-type touch pad.

12. A light source adjusting and controlling switch device, which is installed inside a remote controller, comprising:
a control circuit, said control circuit comprising a microprocessor, a touch sensor, a transfer circuit, and a supply power device for supply DC; and
a capacitance-type touch pad mounted on a surface of said remote controller and connected with said control circuit, comprising at least one detection element connected with said touch sensor of said control circuit; wherein, when a user touches said capacitance-type touch pad with his finger, a capacitance produced on said capacitance-type touch pad will be sensed by said at least one detection element and further sending a corresponding capacitance variable amount signal to a lamp or a wall switch through said transfer circuit connected with said microprocessor of said control circuit wirelessly for switch on/off, brightness and color to said light source immediately.

13. The light source adjusting and controlling switch device as claimed in claim 12, wherein said capacitance-type touch pad further comprises a plurality of light indicator corresponding to said at least one detection element on the surface thereof.

14. The light source adjusting and controlling switch device as claimed in claim 12, wherein said capacitance-type touch pad can be a transparent board and adds a fluorescent agent for indicating.

15. The light source adjusting and controlling switch device as claimed in claim 12, wherein said lamp or said wall switch comprises a receiving circuit for receiving said signal from said remote controller.

16. The light source adjusting and controlling switch device as claimed in claim 12, wherein said wireless transfer mode can be a radio, an infrared and a Bluetooth technology.
